(19) United States
(12) Patent Application Publication
(10) Pub. No.: US 2005/0275080 A1
(43) Pub. Date: Dec. 15, 2005

(54) Multi-chip module package structure

(76) Inventor: Chih-Ming Chung, Ta-She Hsiang (TW)

Correspondence Address: J C PATENTS, INC., 4 VENTURE, SUITE 250, IRVINE, CA, 92618, US

(21) Appl. No.: 10/854,131

(22) Filed: May 26, 2004

(51) Int. Cl. H01L 23/02

(52) U.S. Cl. 257/686

(57) ABSTRACT

The present invention relates to a multi-chip module package structure including a substrate with at least a slot, at least a first and a second chips and a molding compound. The first chip is larger than the second chip. The two chips are respectively disposed on two opposite surfaces of the substrate, while the slot exposes the bonding pads of the first chip. The bonding pads of the first chip are electrically connected to the top surface of the substrate by wire bonding. The second chip is electrically attached to the substrate by flip chip bonding or wire bonding. The molding compound at least covers the first and second chips and a portion of the substrate.

### BACKGROUND OF THE INVENTION

1. Field of Invention

The present invention relates to a multi-chip module package structure. More particularly, the present invention relates to a multi-chip module package structure with less warpage.

2. Description of Related Art

In the semiconductor industry, integrated circuits (ICs) manufacture can be categorized as three stages: fabrication of the wafers, fabrication of the ICs and packaging of the ICs. Through wafer preparation, circuitry design, mask fabrication and wafer dicing, the bare dies are obtained. Each die has bonding pads for outwardly electrical connections. Encapsulation of the die using the molding materials is carried, so that the die is protected from the influences of moisture, heat and noises. The package of the die can provide the medium for electrical connection between the die and the outward circuit, for example, printed circuit board (PCB) or other package substrate.

In semiconductor packaging, wires or bumps are used as medium for electrically connecting the die to the substrate. As the packaging integration is increased, multi-chip module (MCM) packages have increasingly been widely applied in the semiconductor packaging processes.

FIG. 1 is a cross-sectional view of one prior art MCM package. Referring to FIG. 1, the MCM package 100 includes a substrate 110, two chips 130, 150 and a molding compound 170. The chip 130 is a logic chip and the chip 150 is a memory chip, for example. The area of chip 130 is larger than that of the chip 150. The chip 150 is disposed on the top surface of the substrate 110 through bumps 152, and a stiffener ring 140 is disposed on the substrate 110 and around the chip 150. The chip 130 is disposed on the stiffener ring 140 and the chip 150. The chip 130 is electrically connected to the substrate 110 through wires 132. The molding compound 170 covers the top surface of the substrate and the chips 130, 150 and the wires 132. Additionally, bonding pads 112 and solder balls 114 are disposed on the back surface of the substrate 110.

FIG. 2 is a cross-sectional view of another prior art MCM package. Referring to FIG. 2, the MCM package 200 includes a substrate 210, two chips 230, 250 and a molding compound 270. The chip 250 is a logic chip and the chip 230 is a memory chip, for example. The area of chip 230 is larger than that of the chip 250. The backside of chip 230 is attached to the top surface of the substrate 210 and the chip 230 is electrically connected to the substrate 210 through wires 232. The backside of the chip 250 is attached onto the chip 230 and electrically connected to the substrate 210 through wires 252. The molding compound 270 covers the top surface of the substrate and the chips 230, 250 and the wires 232, 252. Additionally, bonding pads 212 and solder balls 214 are disposed on the back surface of the substrate 210.

However, for the package structure of FIG. 1, the stiffener ring 140 between the chip 150 and the chip 130 is required for strengthening and preventing the chip 130 from cracking. Moreover, since the wires 132 are thin (with small cross-section) and long, the transmitted signal may decay rapidly, thus causing signal delay and reducing signal transmission efficiency.

On the other hand, with the package structure of FIG. 2, since the substrate 210 is larger, the substrate 210 often suffers warpage due to the coefficient of thermal expansion (CTE) mismatch between the substrate and the chip. Similarly, because the wires 252 are thin (with small cross-section) and long, the transmitted signal may decay rapidly, thus causing signal delay and reducing signal transmission efficiency. Moreover, if the area of the chip 250 is much smaller than that of the chip 230, the long wires 250 is easily to deform and cause shorts to the adjacent wires.

### SUMMARY OF THE INVENTION

The present invention provides a multi-chip module (MCM) package structure with less warpage by reducing the stress due to CTE mismatch between the substrate and the chip.

The present invention provides a MCM package structure, which can reduce the signal transmission path between the chip and the substrate, for improving the signal transmission efficiency.

The present invention provides a MCM package structure, which offers higher integration.

As embodied and broadly described herein, the present invention provides a multi-chip module package structure including a substrate with at least a slot, at least a first and a second chips and a molding compound. The first and second chips are respectively disposed on the bottom surface and the top surface of the substrate, while the slot exposes the bonding pads of the first chip. The bonding pads of the first chip are electrically connected to the top surface of the substrate by wire bonding, and the second chip is electrically connected to the top surface of the substrate by either wire bonding or flip chip bonding. The first chip is larger than the second chip. The molding compound at least covers the first and second chips and a portion of the substrate.

According to the embodiment, a third chip can be further included in the package structure, and the third chip is disposed on the second chip and electrically connected to the substrate.

Because the substrate includes at least one or more slots, thermal stress due to CTE mismatch between the chips and the substrate can be alleviated and warpage of the substrate or package structure is avoided.

Moreover, since the chips are attached to the opposite surfaces of the substrate, the signal transmission paths are shortened and the transmission efficiency is improved. Additionally, the stiffener ring is no longer needed for supporting the chip.

Accordingly, the MCM package structure can offer higher package integration by holding more chips under the same wire length.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of one prior art MCM package.

FIG. 2 is a cross-sectional view of another prior art MCM package.

FIG. 3 is a top view of the MCM package structure according to the first preferred embodiment of the present invention.

FIG. 4 is a cross-sectional of the MCM package structure according to the first preferred embodiment of the present invention.

FIG. 5 is a cross-sectional of the MCM package structure according to the second preferred embodiment of the present invention.

FIG. 6 is a cross-sectional of the MCM package structure according to the third preferred embodiment of the present invention.

FIG. 6A is a cross-sectional of another MCM package structure according to the third preferred embodiment of the present invention.

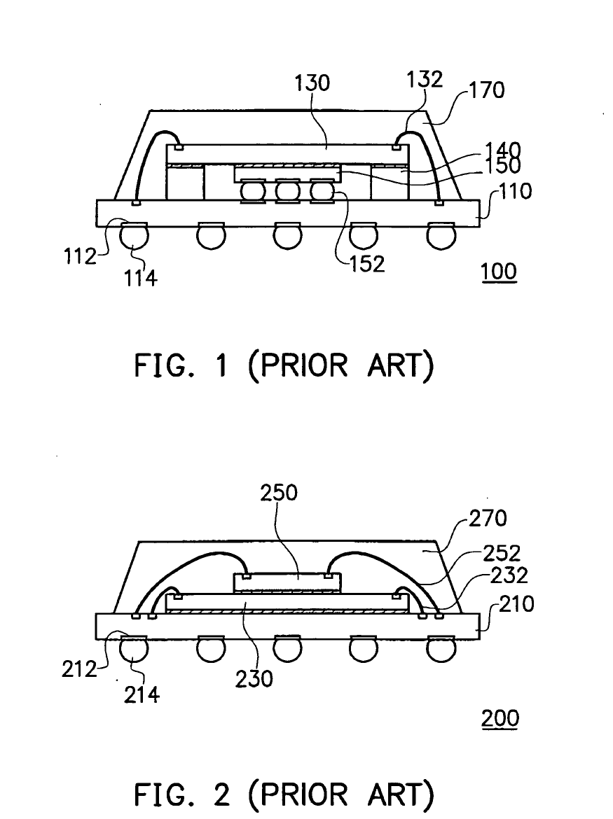

### DESCRIPTION OF THE PREFERRED EMBODIMENTS

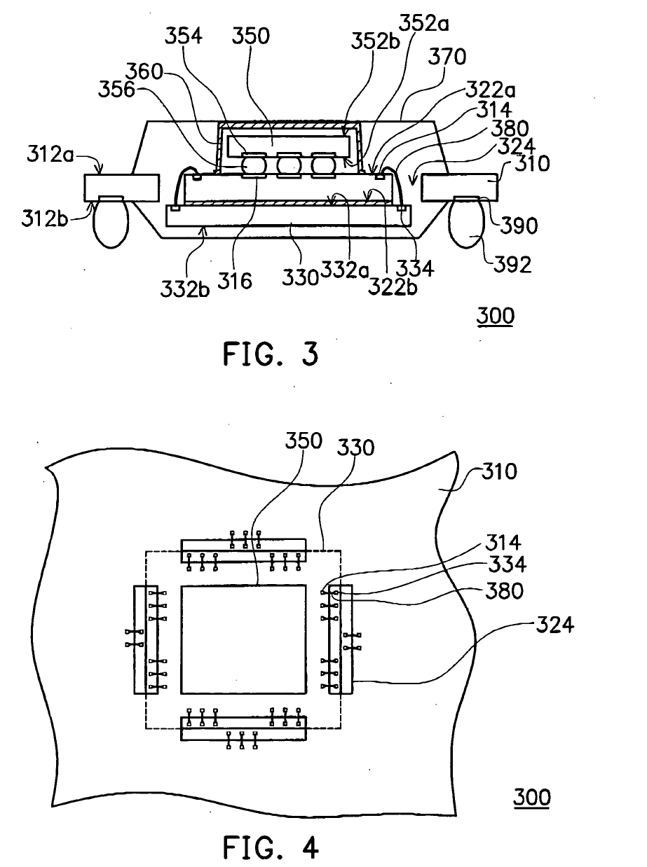

FIG. 3 is a top view of the MCM package structure according to the first preferred embodiment of the present invention. FIG. 4 is a cross-sectional of the MCM package structure according to the first preferred embodiment of the present invention.

Referring to FIG. 3, the package structure 300 at least comprises a substrate 310, chips 330, 350 and a molding compound 370. For example, the chip 330 is a logic chip, and the chip 350 is a memory chip. The chip 330 has an area larger than that of the chip 350.

The chip 330 has an active surface 332a and an opposite back surface 332b. The chip 330 includes a plurality of bonding pads 334, surrounding the periphery of the chip 330 and disposed on the active surface 332.

The substrate 310 is provided with a top surface 312a and a bottom surface 312b, and the top and bottom surfaces 312a/312b respectively include chip disposition regions 322a/322b. The active surface 332a of the chip 330 is attached to the chip disposition region 322b via adhesives. Moreover, the substrate 310 includes a plurality of slots 324 corresponding to the locations of the bonding pads 334, and the slots 324 at least expose the bonding pads 334 of the chip 330. As shown in FIG. 4, four slots 324 are disposed surrounding the chip disposition region 322b. However, the number and the shape of the slot(s) are not limited by the descriptions in the embodiments.

The substrate 310 further comprises a plurality of wiring contacts 314 and a plurality of bumping contacts 316. The bumping contacts 316 are disposed in the chip disposition region 322a of the top surface 312a of the substrate 310. A portion of the wiring contacts 314 are disposed in the chip disposition region 322a and close to one side of the slot 324, while another portion of the wiring contacts 314 are disposed on the top surface 312a of the substrate 310 and close to one side of the slot 324.

The chip 350 includes an active surface 352a and the corresponding back surface 352b. The chip 350 comprises a plurality of bumping pads 354 on the active surface 352a of the chip 350. The chip 350 is electrically connected to the substrate 310 through bumps 356 joined to both the bumping pads 354 and the bumping contacts 316 in the chip disposition region 322a.

Optionally, a heat spreader 360 can be arranged on or above the chip 350 for heat dissipation. The heat spreader 360 can be in a plate shape arranged on the back surface 352b of the chip 350. Alternatively, the heat spreader 360 can be in a reverse cup (or hat) structure including a top (roof) portion, sidewalls and/or a flange portion, disposed on the top surface 312a of the substrate 310 and above and covering the chip 350. Preferably, the heat spreader 360 may be arranged in the chip disposition region 322a of the substrate 310, between the slots 324.

Moreover, the chip 330 is electrically connected to the substrate 310 through wires 380 by wire bonding. One end of the wire 380 is connected to the bonding pad 334 of the chip 330, while the other end of the wire 380 is connected to the wiring contact 314 of the substrate 310.

The molding compound 370 covers the chips 330, 350, wires 380, bumps 356 and a portion of the substrate 310. If the heat spreader 360 is used, the molding compound 370 covers only a portion of the heat spreader 360. Preferably, the surface of the heat spreader 360 is exposed from the molding compound for assisting heat dissipation. On a portion of the bottom surface 312b that is not covered by the molding compound 370, a plurality of ball pads 390 and a plurality of solder balls 392 on the pads 390 are arranged.

For the MCM package structure 300, because the substrate 310 has slots 324, thermal stress due to CTE mismatch between the chips 330, 350 and the substrate 310 can be alleviated by the slots 324. Hence, warpage of the substrate 310 is avoided.

Furthermore, since the chips 330, 350 are respectively attached to the chip disposition region 322b, 322a of the bottom surface 312b and top surface 312a of the substrate 310, the signal transmission paths between the substrate and the chips are similarly short. Therefore, the signal transmission paths are shortened and the signal transmission efficiency is increased. Moreover, the problems of shorts caused by long wires can be avoided, even if one chip is much larger than another chip. In addition, because the chips are not stacked on each other, but are respectively attached to two opposite surfaces of the substrate, no stiffener ring is needed.

In the above embodiment, the chip 350 is connected to the substrate 310 by flip chip technology. However, other equivalent mechanism or technologies can be employed, and the scope of the present invention is not limited to the descriptions of the embodiments.

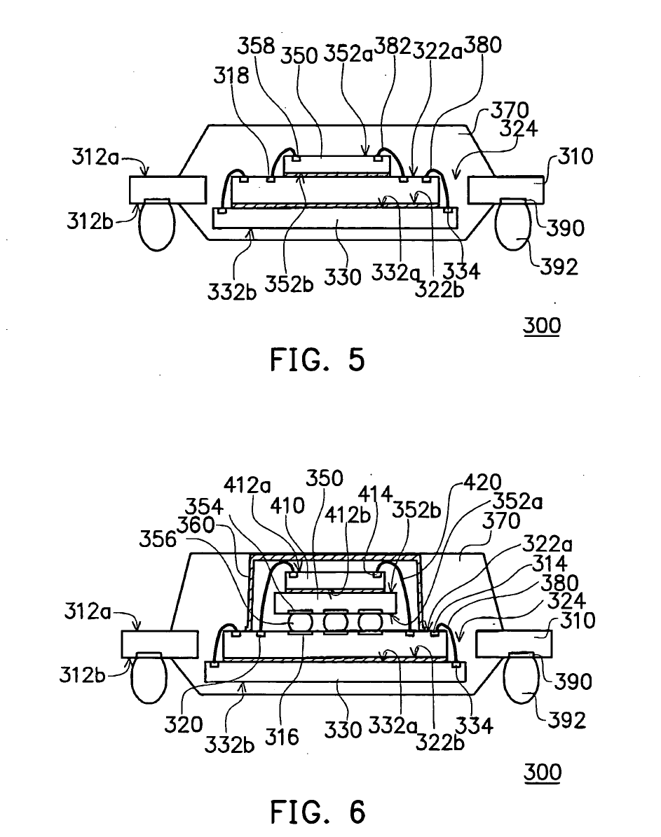

FIG. 5 is a cross-sectional of the MCM package structure according to the second preferred embodiment of the present invention. The same reference numbers used in FIGS. 3 and 4 can be used in this embodiment for representing the same elements. In the second embodiment, the back surface 352b of the chip 350 is attached to the chip disposition region 322a of the top surface 312a of the substrate 310, via adhesives. Instead of using bumping pads 354, the chip 350 in FIG. 5 comprises a plurality of bonding pads 358 on the active surface 352a of the chip 350 and surrounding the periphery of the chip 350. Instead of using bumping contacts 316, a plurality of wiring contacts 318 are disposed around the chip disposition region 322a of the top surface 312a of the substrate 310 The chip 350 is electrically connected to the substrate 310 through wires 382 connected to both the bonding pads 358 and the wiring contacts 318 in the chip disposition region 322a.

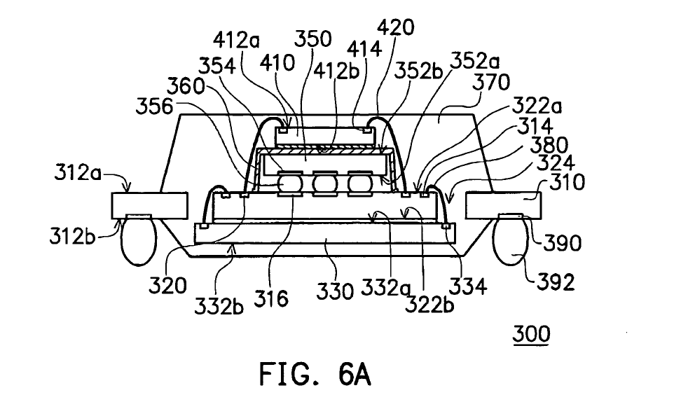

According to the first embodiment, the chips 330, 350 are attached to the bottom and top surfaces 312b, 312a of the substrate 310. Nevertheless, the scope of the present invention is not limited to the descriptions of the embodiments. FIG. 6 is a cross-sectional of the MCM package structure according to the third preferred embodiment of the present invention. The same reference numbers used in FIGS. 3 and 4 can be used in this embodiment for representing the same elements. In the third embodiment, the package structure 300 further includes a chip 410 having an active surface 412a and the corresponding back surface 412b. The chip 410 includes a plurality of bonding pads 414 disposed on the active surface 412a and surrounding the periphery of the chip 410. Corresponding to the bonding pads 414, a plurality of wiring contacts 320 are disposed on the top surface 312a of the substrate 310. For the package structure including the heat spreader 360 over the chip 350, the heat spreader 360 is arranged above the chip 410, while the back surface 412b of the chip 410 is attached to the back surface 352b of the chip 350, as shown in FIG. 6. Alternatively, the back surface 412b of the chip 410 is attached to the heat spreader 360, and the heat spreader 360 is disposed on the back surface 352b of the chip 350, as shown in FIG. 6A. The chip 410 is electrically connected to the substrate 310 through wires 420 by wire bonding. One end of the wire 420 is connected to the bonding pad 414 of the chip 410, while the other end of the wire 420 is connected to the wiring contact 320 of the substrate 310.

For the MCM package structure of FIG. 6, more chips (330, 350, 410) are included within the package structure, thus increasing the package integration. Even if considering the length of wire 420 is comparable to the prior art, at least one more chip is arranged within the package structure without increasing the wire length.

In conclusion, the present invention has at least the following advantages:

1. Because the slots arranged in the substrate, the stress due to CTE mismatch between the chip and the substrate is decreased and warpage of the package structure is greatly reduced.

2. Because the chips are respectively attached to the top and bottom surfaces of the substrate, the signal transmission paths between the substrate and the chips are similarly short. Therefore, the signal transmission paths are shortened and the signal transmission efficiency is improved.

3. No stiffener ring is needed for supporting the chips.

4. More chips can be included within the package structure without increasing the length of the wire when compared with the prior package structure. Hence, the package integration is increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A multi-chip module package structure, comprising:
a first chip having an active surface and a plurality of bonding pads disposed on the active surface of the first chip;
a substrate having a top surface and a bottom surface and comprising at least a slot, wherein the active surface of the first chip is attached to the bottom surface of the substrate and the slot exposes the bonding pads and a peripheral portion of the first chip;
a plurality of first wires, wherein the bonding pads of the first chip are electrically connected to the top surface of the substrate through the first wires;
a second chip, disposed on the top surface of the substrate and electrically connected to the top surface of the substrate; and
a molding compound, covering the first and second chips, the first wires and a portion of the substrate.

2. The package structure of claim 1, further comprising a plurality of bumps disposed between the second chip and the substrate, wherein the second chip is electrically connected to the substrate through the bumps.

3. The package structure of claim 1, further comprising a third chip stacked on the second chip, wherein the third chip is electrically connected to the top surface of the substrate.

4. The package structure of claim 3, further comprising a plurality of second wires, wherein the third chip is electrically connected to the top surface of the substrate through the second wires.

5. The package structure of claim 1, further comprising a plurality of solder balls disposed on the substrate that is not covered by the molding compound.

6. The package structure of claim 1, further comprising a plurality of solder balls disposed on a portion of the bottom surface of the substrate that is not covered by the molding compound.

7. The package structure of claim 1, wherein the first chip has an area larger than that of the second chip.

8. A multi-chip module package structure, comprising:
a first chip having an active surface and a plurality of bonding pads disposed on the active surface of the first chip;
a substrate having a top surface and a bottom surface and comprising at least a slot, wherein the active surface of the first chip is attached to the bottom surface of the substrate and the slot exposes the bonding pads and a peripheral portion of the first chip;
a plurality of first wires, wherein the bonding pads of the first chip are electrically connected to the top surface of the substrate through the first wires;
a second chip, disposed on the top surface of the substrate and electrically connected to the top surface of the substrate by flip chip bonding;
a heat spreader disposed over the second chip; and
a molding compound, covering the first and second chips, the first wires, a portion of the heat spreader and a portion of the substrate.

9. The package structure of claim 8, further comprising a plurality of bumps disposed between the second chip and the substrate, wherein the second chip is electrically connected to the substrate through the bumps.

10. The package structure of claim 8, further comprising a third chip interposed between the second chip and the heat spreader, wherein the third chip is electrically connected to the top surface of the substrate.

11. The package structure of claim 8, further comprising a third chip disposed over the heat spreader, wherein the third chip is electrically connected to the top surface of the substrate.

12. The package structure of claim 10, further comprising a plurality of second wires, wherein the third chip is electrically connected to the top surface of the substrate through the second wires.

13. The package structure of claim 8, further comprising a plurality of solder balls disposed on the substrate that is not covered by the molding compound.

14. The package structure of claim 8, wherein the first chip has an area larger than that of the second chip.

15. The package structure of claim 8, wherein at least a surface of the heat spreader is exposed out of the molding compound.

16. A multi-chip module package structure, comprising:
a first chip having an active surface and a plurality of bonding pads disposed on the active surface of the first chip;
a substrate having a top surface and a bottom surface and comprising at least a slot, wherein the active surface of the first chip is attached to the bottom surface of the substrate and the slot exposes the bonding pads;
a plurality of first wires, wherein the bonding pads of the first chip are electrically connected to the top surface of the substrate through the first wires;
a second chip, disposed on the top surface of the substrate and electrically connected to the top surface of the substrate by wire bonding; and
a molding compound, covering the first and second chips, the first wires and a portion of the substrate.

17. The package structure of claim 16, further comprising a plurality of second wires, wherein the second chip is attached to the top surface of the substrate and electrically connected to the top surface of the substrate through the second wires.

18. The package structure of claim 16, further comprising a third chip stacked on the second chip, wherein the third chip is electrically connected to the top surface of the substrate.

19. The package structure of claim 18, further comprising a plurality of third wires, wherein the third chip is electrically connected to the top surface of the substrate through the third wires.

20. The package structure of claim 16, further comprising a plurality of solder balls disposed on a portion of the bottom surface of the substrate that is not covered by the molding compound.

21. The package structure of claim 16, wherein the first chip has an area larger than that of the second chip.
